(19) United States
(12) Patent Application Publication
(10) Pub. No.: US 2025/0231250 A1
(43) Pub. Date: Jul. 17, 2025

(54) METHOD AND APPARATUS FOR DIAGNOSING ABNORMALITY IN ECO-FRIENDLY VEHICLE BATTERY

(71) Applicants: Hyundai Motor Company, Seoul (KR); Kia Corporation, Seoul (KR)

(72) Inventor: Jung Hyun LEE, Yongin-si (KR)

(73) Assignees: Hyundai Motor Company, Seoul (KR); Kia Corporation, Seoul (KR)

(21) Appl. No.: 18/929,836

(22) Filed: Oct. 29, 2024

(30) Foreign Application Priority Data
Jan. 11, 2024 (KR) 10-2024-0004881

(51) Int. Cl. G01R 31/392; B60L 15/20; B60L 58/12; G01R 31/3835

(52) U.S. Cl. CPC G01R 31/392; B60L 15/2009; B60L 58/12; G01R 31/3835; B60L 2240/12

(57) ABSTRACT

In a method and an apparatus for diagnosing abnormality in an eco-friendly vehicle battery, the method includes determining and storing a defective cell candidate based on a voltage change of each of cells forming a battery module during an ignition OFF mode period of the vehicle, increasing a counter value based on a comparison result of a defective cell candidate during a recent ignition OFF mode period and a defective cell candidate during an immediately previous ignition OFF mode period, and detecting a cell abnormality based on whether a current counter value is greater than or equal to a threshold counter value.

### CROSS REFERENCE TO RELATED APPLICATIONS

The present application claims priority to Korean Patent Application No. 10-2024-0004881, filed Jan. 11, 2024, the entire contents of which is incorporated herein for all purposes by this reference.

### BACKGROUND OF THE PRESENT DISCLOSURE

### Field of the Present Disclosure

The present disclosure relates to a battery management system. More particularly, the present disclosure relates to a method and an apparatus for diagnosing abnormality in an eco-friendly vehicle battery.

### Description of Related Art

Eco-friendly vehicles such as a hybrid electronic vehicle (HEV), a plug-in HEV (PHEV), and an electronic vehicle (EV) have a battery which is a storage device to store electrical energy to drive a motor, and particularly, have a high-voltage battery which is different from a low-voltage battery mounted on existing engine vehicles.

As such a high-voltage battery has increasingly high density and high energy, even minor quality issues may lead to dangerous situations such as a fire. Accordingly, battery safety becomes increasingly important. Monitoring logic for battery safety is also applied to electric vehicles already in mass production, but is still insufficient to prevent accidents by detecting abnormal signs of a battery in advance.

Therefore, in the present field of the present disclosure, there is a demand for technology that can prevent accidents by detecting abnormal signs of a battery in advance.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a technology that can detect abnormal signs of a battery in advance.

Another technical objective of the present disclosure is to provide logic that can diagnose high-voltage batteries by diagnosing cells with abnormal signs by use of a cell balancing technology for balancing voltage deviations in the high-voltage batteries.

The technical objectives intended to be achieved in an exemplary embodiment of the present disclosure are not limited to the technical objectives mentioned above, and other technical objectives not mentioned will be clearly understood by those skilled in the art to which the present disclosure belongs from the description below.

To achieve the objectives of the present disclosure, there is provided a method for diagnosing abnormality in an eco-friendly vehicle battery according to an exemplary embodiment of the present disclosure, the method including: determining and storing a defective cell candidate based on a voltage change of each of cells forming a battery module during an ignition OFF mode period of the vehicle; increasing a counter value based on a comparison result of a defective cell candidate during a recent ignition OFF mode period and a defective cell candidate during an immediately previous ignition OFF mode period; and detecting a cell abnormality based on whether a current counter value is greater than or equal to a threshold counter value.

In the instant case, the voltage change of each of the cells during the ignition OFF mode period may be determined based on a difference between a voltage of each of the cells at time at which a vehicle switches from an IG ON mode to an IG OFF mode and a voltage of each of the cells at time at which the vehicle switches from the IG OFF mode to the IG ON mode.

In the instant case, the defective cell candidate may be determined based on the voltage change of each of the cells and an average of voltage changes of all cells forming the battery module.

In the instant case, in the determining and storing of the defective cell candidate, a cell whose value obtained in subtracting the average of the voltage changes of all the cells from the voltage change of each of the cells is greater than a threshold may be determined as a defective cell candidate.

In the instant case, the counter value may be initially set to be ‘zero’ and increase by ‘one’.

In the instant case, the determining and storing of the defective cell candidate may be performed when a state of charge (SOC) value of the battery module is greater than or equal to a threshold rate, and a temperature of the battery module is greater than or equal to a threshold temperature.

In the instant case, in the detecting of the cell abnormality, when the current counter value is greater than or equal to the threshold counter value, a warning message may be transmitted to a driver, and a vehicle may be controlled.

In the instant case, in the increasing of the counter value, when the defective cell candidate during a recent ignition OFF mode period is the same as the defective cell candidate during an immediately previous ignition OFF mode period, the counter value may be increased.

Meanwhile, according to an exemplary embodiment of the present disclosure, there is an apparatus for diagnosing abnormality in an eco-friendly vehicle battery, the apparatus including: a battery configured to store power energy to drive a vehicle and including a plurality of cells; a sensor portion including a voltage sensor configured to detect voltages of the plurality of cells; and a battery management portion configured to determine and store a defective cell candidate based on a voltage change of each of cells forming a battery module during an ignition OFF mode period of the vehicle, increase a counter value based on a comparison result of a defective cell candidate during a recent ignition OFF mode period and a defective cell candidate during an immediately previous ignition OFF mode period, and detect a cell abnormality based on whether a current counter value is greater than or equal to a threshold counter value.

In the instant case, the voltage change of each of the cells during the ignition OFF mode period may be determined based on a difference between a voltage of each of the cells at time at which a vehicle switches from an IG ON mode to an IG OFF mode and a voltage of each of the cells at time at which the vehicle switches from the IG OFF mode to the IG ON mode.

In the instant case, the defective cell candidate may be determined based on the voltage change of each of the cells and an average of voltage changes of all cells forming the battery module.

In the instant case, the battery management portion may be configured to determine a cell whose value obtained in subtracting the average of the voltage changes of all the cells from the voltage change of each of the cells is greater than a threshold as a defective cell candidate.

In the instant case, the counter value may be initially set to be ‘zero’ and increase by ‘one’.

In the instant case, the battery management portion may be configured to determine and store the defective cell candidate when a state of charge (SOC) value of the battery module is greater than or equal to a threshold rate, and a temperature of the battery module is greater than or equal to a threshold temperature.

In the instant case, the battery management portion may transmit a warning message to a driver and control a vehicle when the current counter value is greater than or equal to the threshold counter value.

In the instant case, the battery management portion may increase the counter value when the defective cell candidate during a recent ignition OFF mode period is the same as the defective cell candidate during an immediately previous ignition OFF mode period.

According to various embodiments of the present disclosure as described above, abnormal signs of a battery may be detected in advance.

Furthermore, a cell with an abnormal sign is diagnosed in a situation in which the power of a controller that performs the cell balancing of a high-voltage battery is turned off, providing logic configured for diagnosing a high-voltage battery.

Additionally, a function of monitoring a high-voltage battery is improved, preventing accidents and enhancing the safety of an eco-friendly vehicle.

Effects which may be obtained from the present disclosure are not limited to the effects mentioned above, and other effects not mentioned may be clearly understood by those skilled in the art to which the present disclosure belongs from the description below.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram schematically illustrating a battery abnormality diagnosis apparatus according to an exemplary embodiment of the present disclosure;

FIG. 2 illustrates an example in which the average voltage of battery cells and the voltage of defective cells decrease when a vehicle repeatedly turns its ignition on or off; and

FIG. 3A and FIG. 3B are flowcharts illustrating a method for diagnosing a battery abnormality according to the exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereafter, various exemplary embodiments of the present disclosure will be described in detail with reference to the accompanying drawings and the same or similar components are provided the same reference numerals regardless of the numbers of figures and are not repeatedly described. Terms “module” and “unit” that are used for components in the following description are used only for the convenience of description without including discriminate meanings or functions. Furthermore, in the following description, if it is decided that the detailed description of known technologies related to the present disclosure makes the subject matter of the exemplary embodiments described herein unclear, the detailed description is omitted. Furthermore, the accompanying drawings are provided only for easy understanding of embodiments disclosed in the specification, and the technical spirit disclosed in the specification is not limited by the accompanying drawings, and all changes, equivalents, and replacements should be understood as being included in the spirit and scope of the present disclosure.

Terms including ordinal numbers such as “first” and “second”, etc. may be used to describe various components, but the components are not to be construed as being limited to the terms. The terms are used only to distinguish one component from another component.

It is to be understood that when one element is referred to as being “connected to” or “coupled to” another element, it may be directly connected to or directly coupled to another element or be connected to or coupled to another element, but yet another element may intervene therebetween. On the other hand, it should be understood that when one element is referred to as being “connected directly to” or “coupled directly to” another element, it is connected to or coupled to another element without yet another element intervening therebetween.

Singular forms are intended to include plural forms unless the context clearly indicates otherwise.

It will be further understood that terms such as “comprise” or “have” used in the present specification specify the presence of stated features, steps, operations, components, parts, or a combination thereof, but do not preclude the presence or addition of one or more other features, numerals, steps, operations, components, parts, or a combination thereof.

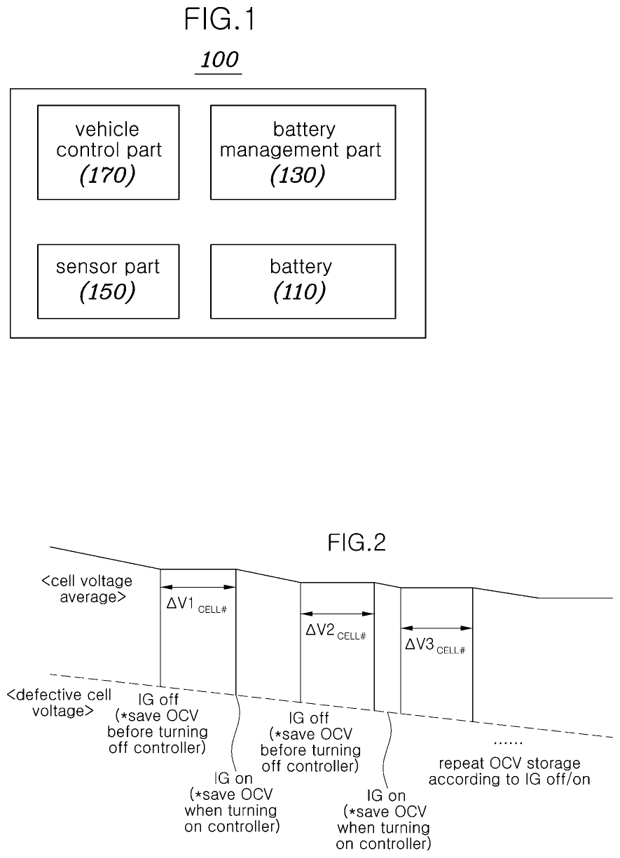

FIG. 1 is a block diagram schematically illustrating a battery abnormality diagnosis apparatus according to an exemplary embodiment of the present disclosure.

Referring to FIG. 1, the battery abnormality diagnosis apparatus 100 according to the exemplary embodiment of the present disclosure includes a battery 110, a battery management portion 130, a sensor portion 150, and a vehicle control portion 170.

The battery 110 stores power energy to drive a vehicle and includes a plurality of cells.

The battery management portion 130 is configured to determine defective cells with abnormalities based on the voltage change of each of cells forming the battery 110 and the average value of the voltage changes of all cells while a vehicle is in an ignition off (IG OFF) mode.

In an exemplary embodiment of the present disclosure, the battery management portion 130 may include at least one processor and a memory for storing computer-readable instructions so as to determine the defective cells with abnormalities.

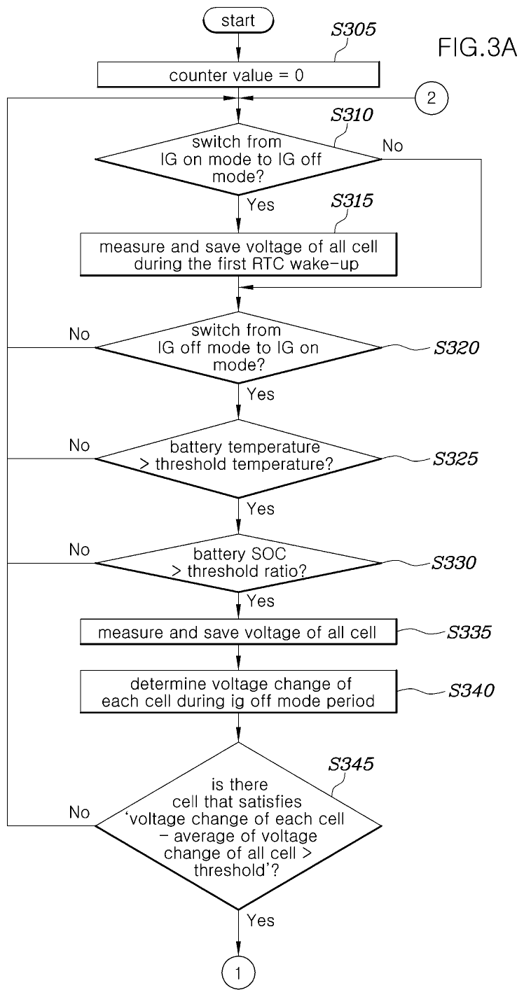

For example, referring to FIG. 2, it may be seen that general good cells have little change in voltage from time at which a vehicle enters the IG OFF mode until time at which the vehicle switches to an ignition on (IG ON) mode, but defective cells have voltages continuously decreasing even in the IG OFF mode, and based on the present decrease of voltages, defective cells may be detected.

Meanwhile, the battery management portion 130 stores a voltage change of each of cells forming the battery 110 and the average of voltage changes of all cells from time at which a vehicle enters an IG OFF mode until time at which the vehicle switches to an IG ON mode in a storage device such as a memory.

In the instant case, based on the measured values of the voltage of each cell immediately before the vehicle enters the IG OFF mode and the voltage of each cell immediately after the vehicle enters the IG ON mode, the battery management portion 130 may be configured to determine the voltage change of each cell and the average of the voltage changes of all cells.

In the instant case, each of the cells may be identified by an identification number, and for example, may be defined as CELL1, CELL2, or CELL3, etc.

Furthermore, the voltage of each cell may be defined as V_{CELL1}, V_{CELL2}, or V_{CELL3}, etc., and the voltage change of each cell from time at which a vehicle enters an IG OFF mode until time at which the vehicle switches to an IG ON mode may be defined as ΔV_{CELL1}, ΔV_{CELL2}, or ΔV_{CELL3}, etc.

In the instant case, the voltage change of each cell may be defined as ΔV1_{CELL1}, ΔV2_{CELL1}, or ΔV3_{CELL1}, etc. depending on the number of times that a vehicle is in an IG OFF mode.

Meanwhile, the averages of the voltage changes of all cells while a vehicle is in an IG OFF mode may be respectively defined as ΔV1_{CELLavg}, ΔV2_{CELLavg}, and ΔV3_{CELLavg}, etc. depending on the number of times that a vehicle is in an IG OFF mode.

In the instant case, the battery management portion 130 may be configured to determine that a cell whose voltage change in an IG OFF mode of each time is by at least a threshold greater than the average voltage change of all cells is a detective cell candidate.

In the instant case, the battery management portion 130 may be configured to determine a defective cell candidate based on whether a value obtained in subtracting the average of the voltage changes of all cells from the voltage change of each cell in an IG OFF mode of each time is greater than a threshold.

In the instant case, the threshold may have various values depending on user setting, and for example, may be set to be 3 mV.

In the instant case, the battery management portion 130 may be configured to determine whether a defective cell candidate whose value obtained in subtracting the average of voltage changes of all cells from a voltage change of each cell in an IG OFF mode of each time is greater than a threshold is the same as a defective cell candidate of a previous time.

For example, the battery management portion 130 may store identifiers or identification numbers of all defective cell candidates in an IG OFF mode of each time, determine whether a defective cell candidate is the same as a defective cell candidate of a previous time, increase, by one, a value of a counter including an initial value set to be ‘zero’ when the defective cell candidate is the same as the defective cell candidate of the previous time, and may store the counter value and the identifier or identification number of each of the defective cell candidates.

Furthermore, when a counter value increased according to the result of determining whether defective cell candidates in an IG OFF mode of each time are the same is greater than or equal to a threshold, the battery management portion 130 is configured to determine that an abnormality has occurred in a corresponding defective cell candidate, and transmits a warning message about a battery abnormality to a driver to control a vehicle.

The sensor portion 150 measures the voltage or temperature of the battery 110.

In the instant case, although not shown in the drawing, the sensor portion 150 may include at least one voltage sensor and/or at least one temperature sensor.

In the instant case, the sensor portion 150 may measure all voltage changes of battery cells forming the battery 110.

The vehicle control portion 170 is configured to control a vehicle based on the output of the battery 110.

In the instant case, the vehicle control portion 170 receives information related to the occurrence of abnormality in the battery 110 from the battery management portion 130 and is configured to control a vehicle based on the information.

For example, when the vehicle control portion 170 receives information related to the occurrence of abnormality in the battery 110 from the battery management portion 130, the vehicle control portion 170 may gradually reduce the speed of a vehicle or control the vehicle to evacuate to a safe place.

In an exemplary embodiment of the present disclosure, the battery management portion 130 and the vehicle control portion 170 may be implemented as separate processor. Alternatively, the battery management portion 130 and the vehicle control portion 170 may be implemented as a single processor.

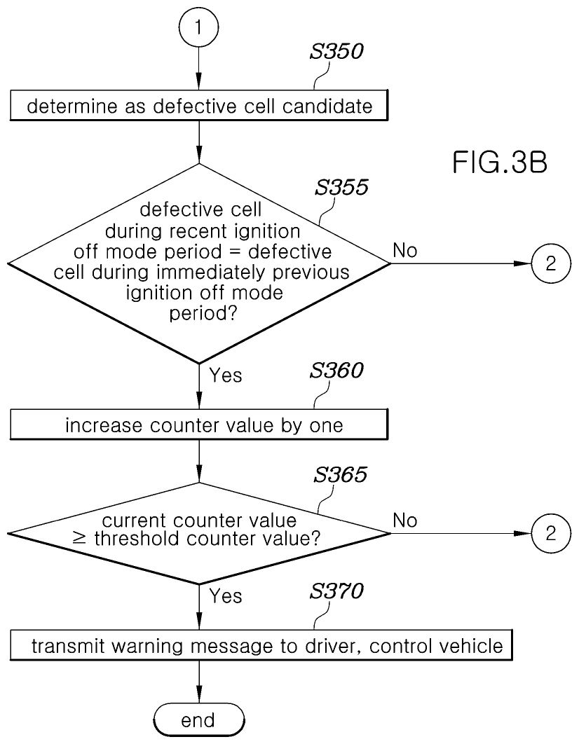

FIG. 3A and FIG. 3B are flowcharts illustrating a method for diagnosing a battery abnormality according to the exemplary embodiment of the present disclosure.

The method for diagnosing a battery abnormality according to the exemplary embodiment of the present disclosure may be performed by the battery management portion 130 of the battery abnormality diagnosis apparatus 100 of FIG. 1.

Referring to FIG. 3A and FIG. 3B, the battery management portion 130 presets the initial value of a counter for diagnosing battery abnormality to be 0 at S305.

Furthermore, the battery management portion 130 is configured to determine whether a vehicle switches from an IG ON mode to an IG OFF mode at S310.

When the vehicle switches from the IG ON mode to IG OFF mode, measures and stores the voltages of all cells when the battery management portion 130 wakes up during the first RTC wake-up at S315.

In the instant case, the battery management portion 130 may store the voltages of all measured cells in a memory inside the battery management portion 130 or a memory linked to the battery management portion 130.

Furthermore, the battery management portion 130 determines whether a vehicle switches from an IG OFF mode to an IG ON mode at S320, determines whether a battery temperature is higher than a threshold temperature at S325 when the vehicle switches from the IG OFF mode to the IG ON mode, determine whether the state of charge (SOC) value of a battery is higher than a threshold rate thereof at S330 when the battery temperature is higher than the threshold temperature, and measures and stores voltages of all cells when the SOC value of a battery is higher than the threshold rate at S335.

In an exemplary embodiment of the present disclosure, the order of S325 and S335 may not be limited thereto but could be the order of S335 and S325.

In the instant case, the threshold temperature may be a value arbitrarily preset by user setting, for example, 0° C.

In the instant case, the threshold value may be a value arbitrarily preset by user setting, for example, 20%.

Meanwhile, as a result of the determination at S310, when a vehicle does not switch from the IG ON mode to the IG OFF mode, the determination at S320 is performed without performing the step of S315.

Furthermore, as a result of the determination at S320, when a vehicle does not switch from the IG OFF mode to the IG ON mode, or as a result of the determination at S325, when the battery temperature is not higher than the threshold temperature, or as a result of the determination at S330, when the state of charge (SOC) value of a battery is not higher than the threshold rate, the determination of the step S310 is performed.

Furthermore, the battery management portion 130 is configured to determine the voltage change of each cell during an IG OFF mode period at S340 based on the difference between the voltage of all cells stored at S315 and the voltage of all cells measured at S335.

Furthermore, the battery management portion 130 is configured to determine whether there is a cell that satisfies a condition in which a value obtained in subtracting the average of the voltage changes of all cells from the voltage change of each cell is greater than a threshold at S345.

As a result of the determination at S345, when there is a cell that satisfies the condition in which a value obtained in subtracting the average of the voltage changes of all cells from the voltage change of each cell is greater than a threshold, the cell that satisfies the above condition is determined as a defective cell candidate at S350.

Furthermore, the battery management portion 130 is configured to determine whether a defective cell candidate during a recent ignition OFF mode period is the same as a defective cell candidate during an immediately previous ignition OFF mode period at S355.

As the result of the determination at S355, when the defective cell candidate during a recent ignition OFF mode period is the same as the defective cell candidate during an immediately previous ignition OFF mode period, a counter value is increased by one at S360.

Furthermore, the battery management portion 130 is configured to determine whether a current counter value is greater than or equal to a threshold counter value at S365.

As the result of the determination at S365, when the current counter value is greater than or equal to the threshold counter value, the battery management portion 130 transmits a warning message about a battery abnormality to a driver and is configured to control a vehicle at S370.

In the instant case, the warning message may be transmitted through the display screen or speaker of the vehicle.

In the instant case, the battery management portion 130 may transmit information related to the occurrence of battery abnormality to the vehicle control portion 170 to control the vehicle.

For example, when the vehicle control portion 170 receives information related to the occurrence of abnormality in the battery 110 from the battery management portion 130, the vehicle control portion 170 may gradually reduce the speed of the vehicle or control the vehicle to evacuate to a safe place.

According to the exemplary embodiments of the present disclosure described so far, abnormal signs of a battery may be detected in advance.

Furthermore, a cell with an abnormal sign is diagnosed in a situation in which the power of a controller that is configured to perform the cell balancing of a high-voltage battery is turned off, providing logic configured for diagnosing a high-voltage battery.

Additionally, a function of monitoring a high-voltage battery is improved, preventing accidents and enhancing the safety of an eco-friendly vehicle.

Furthermore, the term related to a control device such as “controller”, “control apparatus”, “control unit”, “control device”, “control module”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured for processing data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A method for diagnosing abnormality in a vehicle battery, the method comprising:
determining, by a proceeeor, and storing a defective cell candidate based on a voltage change of each of cells forming a battery module during an ignition (IG) OFF mode period of a vehicle;
increasing a counter value based on a comparison result of a defective cell candidate during a recent ignition OFF mode period and a defective cell candidate during a previous ignition OFF mode period; and
detecting a cell abnormality based on whether a current counter value is greater than or equal to a threshold counter value.

2. The method of claim 1, wherein the voltage change of each of the cells during the ignition OFF mode period is determined based on a difference between a voltage of each of the cells at time at which the vehicle switches from an IG ON mode to an IG OFF mode and a voltage of each of the cells at time at which the vehicle switches from the IG OFF mode to the IG ON mode.

3. The method of claim 1, wherein in the determining and storing of the defective cell candidate, the defective cell candidate is determined based on the voltage change of each of the cells and an average of voltage changes of all cells forming the battery module.

4. The method of claim 3, wherein in the determining and storing of the defective cell candidate,
a cell whose value obtained in subtracting the average of the voltage changes of all the cells from the voltage change of each of the cells is greater than a threshold is determined as the defective cell candidate based on the voltage change.

5. The method of claim 1, wherein the counter value is initially set to be ‘zero’ and increases by ‘one’.

6. The method of claim 1, wherein the determining and storing of the defective cell candidate is performed in response that a state of charge (SOC) value of the battery module is greater than or equal to a threshold rate, or a temperature of the battery module is greater than or equal to a threshold temperature.

7. The method of claim 1, wherein in the detecting of the cell abnormality, in response that the current counter value is greater than or equal to the threshold counter value, a warning message is transmitted by the processor to a driver, and the vehicle is controlled by the processor.

8. The method of claim 7, wherein, in response that the cell abnormality is detected, the processor is configured to reduce a speed of the vehicle.

9. The method of claim 1, wherein in the increasing of the counter value, in response that the defective cell candidate during the recent ignition OFF mode period is the same as the defective cell candidate during the previous ignition OFF mode period, the counter value is increased by the processor.

10. An apparatus for diagnosing abnormality in a vehicle battery, the apparatus comprising:
a battery configured to store power energy to drive a vehicle and including a plurality of cells;
a sensor portion including a voltage sensor configured to detect voltages of the plurality of cells; and
a battery management portion operatively connected to the sensor portion and configured to:
determine and store a defective cell candidate based on a voltage change of each of cells forming a battery module during an ignition (IG) OFF mode period of the vehicle,
increase a counter value based on a comparison result of a defective cell candidate during a recent ignition OFF mode period and a defective cell candidate during a previous ignition OFF mode period, and
detect a cell abnormality based on whether a current counter value is greater than or equal to a threshold counter value.

11. The apparatus of claim 10, wherein the voltage change of each of the cells during the ignition OFF mode period is determined based on a difference between a voltage of each of the cells at time at which the vehicle switches from an IG ON mode to an IG OFF mode and a voltage of each of the cells at time at which the vehicle switches from the IG OFF mode to the IG ON mode.

12. The apparatus of claim 10, wherein the defective cell candidate is determined based on the voltage change of each of the cells and an average of voltage changes of all cells forming the battery module.

13. The apparatus of claim 12, wherein the battery management portion is further configured to determine a cell whose value obtained in subtracting the average of the voltage changes of all the cells from the voltage change of each of the cells is greater than a threshold as the defective cell candidate based on the voltage change.

14. The apparatus of claim 10, wherein the counter value is initially set to be ‘zero’ and increases by ‘one’.

15. The apparatus of claim 10, wherein the battery management portion is further configured to determine and store the defective cell candidate based on the voltage change in response that a state of charge (SOC) value of the battery module is greater than or equal to a threshold rate, or a temperature of the battery module is greater than or equal to a threshold temperature.

16. The apparatus of claim 10, wherein the battery management portion is further configured to transmit a warning message to a driver and is configured to control the vehicle in response that the current counter value is greater than or equal to the threshold counter value.

17. The apparatus of claim 16, wherein, upon the detecting of the cell abnormality, the battery management portion is further configured to reduce a speed of the vehicle.

18. The apparatus of claim 10, wherein the battery management portion is further configured to increase the counter value in response that the defective cell candidate during the recent ignition OFF mode period is the same as the defective cell candidate during the previous ignition OFF mode period.
